(19) United States
(12) Patent Application Publication
(10) Pub. No.: US 2011/0156211 A1
(43) Pub. Date: Jun. 30, 2011

(54) SEMICONDUCTOR STRUCTURE FOR REALIZING ESD PROTECTION CIRCUIT

(76) Inventor: Tung-Yang Chen, Tainan County (TW)

(21) Appl. No.: 12/650,468

(22) Filed: Dec. 30, 2009

(51) Int. Cl. H01L 27/06

(52) U.S. Cl. 257/577; 361/56; 257/E27.019

(57) ABSTRACT

The semiconductor structure of the present invention comprises: a P-well, a first N+ diffusion region, a first P+ diffusion region, a second P+ diffusion region, a first N-well, and a second N+ diffusion region. The semiconductor structure of the present invention comprises: a N-well, a first P+ diffusion region, a first N+ diffusion region, a second N+ diffusion region, a first P-well, and a second P+ diffusion region. Compared with the conventional semiconductor structure for realizing an ESD protection circuit, the semiconductor structure of the present invention requires a smaller area by utilizing the parasitic BJT to have the same ESD protection function. Brief summarized, the semiconductor structure disclosed by the present invention can be utilized for realizing an ESD protection circuit in a smaller area to reduce cost.

### BACKGROUND OF THE INVENTION

1. Field of the Invention

The present invention relates to a semiconductor structure, and more particularly, to a semiconductor structure for realizing an ESD protection circuit and reducing cost.

2. Description of the Prior Art

Please refer to FIG. 1 and FIG. 2. FIG. 1 shows a simplified diagram of a conventional semiconductor structure 100. FIG. 2 shows an ESD protection circuit 200 realized by the semiconductor structure 100. As shown in FIG. 1, the semiconductor structure 100 comprises: an N-well 102, a first P+ diffusion region 104, a first N+ diffusion region 106, a second N+ diffusion region 110, and a second P+ diffusion region 112. The first P+ diffusion region 104 and the second N+ diffusion region 110 are coupled to a signal input/output point 202 (shown in FIG. 2). The first N+ diffusion region 106 is coupled to a first voltage level VDDA (shown in FIG. 2), and the second P+ diffusion region 112 is coupled to a second voltage level VSSA (shown in FIG. 2). The semiconductor structure 100 realizes the ESD protection circuit 200 as shown in FIG. 2. A first diode 204 is formed between the first voltage level VDDA and the second voltage level VSSA. A second diode 206 is formed between the signal input/output point 202 and the first voltage level VDDA. A third diode 208 is formed between the signal input/output point 202 and the second voltage level VSSA. However, the conventional semiconductor structure 100 requires a large area in an IC, and thus increases cost.

### SUMMARY OF THE INVENTION

It is therefore one of the objectives of the present invention to provide a semiconductor structure for realizing an ESD protection circuit and reducing cost, so as to solve the above problems.

In accordance with an embodiment of the present invention, a semiconductor structure for realizing an ESD protection circuit is disclosed. The semiconductor structure comprises: a P-well, a first N+ diffusion region, a first P+ diffusion region, a second P+ diffusion region, a first N-well, and a second N+ diffusion region. The first N+ diffusion region is positioned in the P-well, and has a first side, a second side adjacent to the first side, a third side adjacent to the second side, and a fourth side adjacent to the first side and the third side, and the first N+ diffusion region is coupled to a signal input/output point. The first P+ diffusion region is positioned in the P-well and in the first side of the first N+ diffusion region, and coupled to a first voltage level. The second P+ diffusion region is positioned in the P-well and in the third side of the first N+ diffusion region, and coupled to the first voltage level. The first N-well is positioned in the fourth side of the first N+ diffusion region and adjacent to the P-well. The second N+ diffusion region is positioned in the first N-well and coupled to a second voltage level, wherein the second voltage level is higher than the first voltage level. The first N-well has no P+ diffusion region disposed therein. A first diode is formed between the first voltage level and the second voltage level, and a second diode is formed between the signal input/output point and the first voltage level. A parasitic BJT, having an emitter, a base, and a collector, is formed between the first voltage level, the second voltage level, and the signal input/output point, and the emitter of the parasitic BJT is couple to the second voltage level, and the base of the parasitic BJT is couple to the first voltage level, and the collector of the parasitic BJT is couple to the signal input/output point.

In accordance with an embodiment of the present invention, a semiconductor structure for realizing an ESD protection circuit is disclosed. The semiconductor structure comprises: a N-well, a first P+ diffusion region, a first N+ diffusion region, a second N+diffusion region, a first P-well, and a second P+ diffusion region. The first P+ diffusion region is positioned in the N-well, and has a first side, a second side adjacent to the first side, a third side adjacent to the second side, and a fourth side adjacent to the first side and the third side, and the first P+ diffusion region is coupled to a signal input/output point. The first N+ diffusion region is positioned in the N-well and in the first side of the first P+ diffusion region, and coupled to a first voltage level. The second N+ diffusion region is positioned in the N-well and in the third side of the first P+ diffusion region, and coupled to the first voltage level. The first P-well is positioned in the fourth side of the first P+ diffusion region and adjacent to the N-well. The second P+ diffusion region is positioned in the first P-well and coupled to a second voltage level, wherein the second voltage level is lower than the first voltage level. The first P-well has no N+ diffusion region disposed therein. A first diode is formed between the first voltage level and the second voltage level, and a second diode is formed between the signal input/output point and the first voltage level. A parasitic BJT having an emitter, a base, and a collector is formed between the first voltage level, the second voltage level, and the signal input/output point, and the emitter of the parasitic BJT is couple to the signal input/output point, and the base of the parasitic BJT is couple to the first voltage level, and the collector of the parasitic BJT is couple to the second voltage level.

Brief summarized, the semiconductor structure disclosed by the present invention can be utilized for realizing an ESD protection circuit in a smaller area to reduce cost.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a simplified diagram of a conventional semiconductor structure.

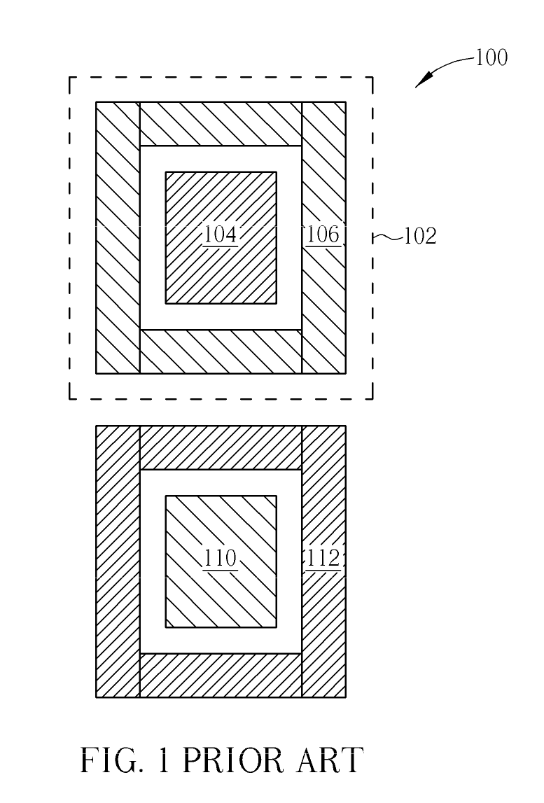

FIG. 2 shows an ESD protection circuit realized by the semiconductor structure in FIG. 1.

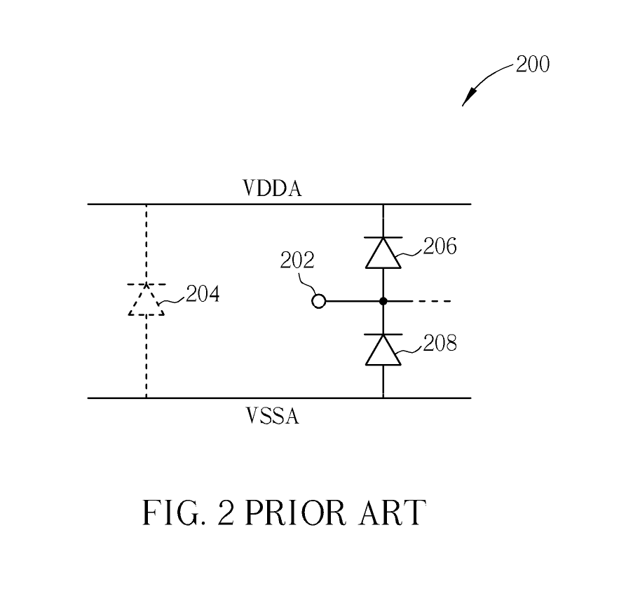

FIG. 3 shows a simplified diagram of a semiconductor structure in accordance with a first embodiment of the present invention.

FIG. 4 shows an ESD protection circuit realized by the semiconductor structure in FIG. 3.

FIG. 5 shows a simplified diagram of a semiconductor structure in accordance with a second embodiment of the present invention.

FIG. 6 shows a simplified diagram of a semiconductor structure in accordance with a third embodiment of the present invention.

FIG. 7 shows a simplified diagram of a semiconductor structure in accordance with a fourth embodiment of the present invention.

FIG. 8 shows a simplified diagram of a semiconductor structure in accordance with a fifth embodiment of the present invention.

FIG. 9 shows a simplified diagram of a semiconductor structure in accordance with a sixth embodiment of the present invention.

FIG. 10 shows an ESD protection circuit realized by the semiconductor structure in FIG. 9.

FIG. 11 shows a simplified diagram of a semiconductor structure in accordance with a seventh embodiment of the present invention.

FIG. 12 shows a simplified diagram of a semiconductor structure in accordance with an eighth embodiment of the present invention.

FIG. 13 shows a simplified diagram of a semiconductor structure in accordance with a ninth embodiment of the present invention.

FIG. 14 shows a simplified diagram of a semiconductor structure in accordance with a tenth embodiment of the present invention.

### DETAILED DESCRIPTION

Certain terms are used throughout the following description and the claims to refer to particular system components. As one skilled in the art will appreciate, manufacturers may refer to a component by different names. This document does not intend to distinguish between components that differ in name but not function. In the following discussion and in the claims, the terms “include”, “including”, “comprise”, and “comprising” are used in an open-ended fashion, and thus should be interpreted to mean “including, but not limited to . . . ” The terms “couple” and “coupled” are intended to mean either an indirect or a direct electrical connection. Thus, if a first device couples to a second device, that connection may be through a direct electrical connection, or through an indirect electrical connection via other devices and connections.

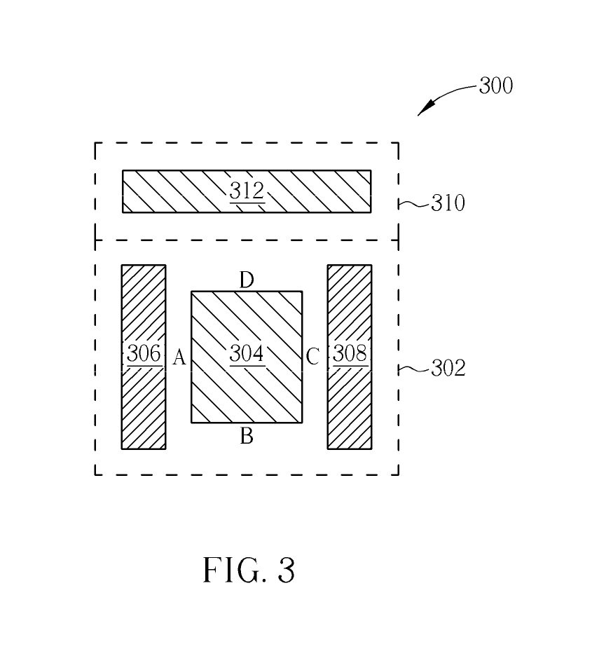

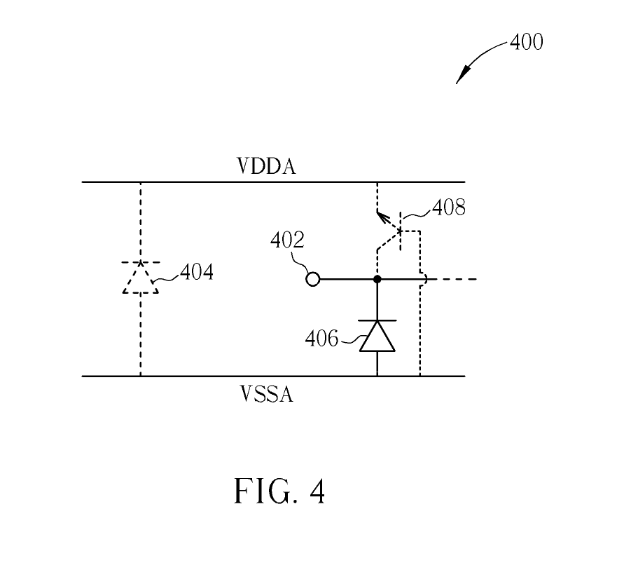

Please refer to FIG. 3 and FIG. 4. FIG. 3 shows a simplified diagram of a semiconductor structure 300 in accordance with a first embodiment of the present invention. FIG. 4 shows an ESD protection circuit 400 realized by the semiconductor structure 300. As shown in FIG. 3, the semiconductor structure 300 comprises: a P-well 302, a first N+ diffusion region 304, a first P+ diffusion region 306, a second P+ diffusion region 308, a first N-well 310, and a second N+ diffusion region 312. The first N+ diffusion region 304 is positioned in the P-well 302, and has a first side A, a second side B adjacent to the first side A, a third side C adjacent to the second side B, and a fourth side D adjacent to the first side A and the third side C, and the first N+ diffusion region 304 is coupled to a signal input/output point 402 (shown in FIG. 4). The first P+ diffusion region 306 is positioned in the P-well 302 and in the first side A of the first N+ diffusion region 304, and coupled to a first voltage level VSSA (shown in FIG. 4). The second P+ diffusion region 308 is positioned in the P-well 302 and in the third side C of the first N+ diffusion region 304, and coupled to the first voltage level VSSA. The first N-well 310 is positioned in the fourth side D of the first N+ diffusion region 304 and adjacent to the P-well 302. The second N+ diffusion region 312 is positioned in the first N-well 310 and coupled to a second voltage level VDDA (shown in FIG. 4), wherein the second voltage level VDDA is higher than the first voltage level VSSA. The first N-well 310 has no P+ diffusion region disposed therein. The semiconductor structure 300 realizes the ESD protection circuit 400 as shown in FIG. 4. A first diode 404 is formed between the first voltage level VSSA and the second voltage level VDDA, and a second diode 406 is formed between the signal input/output point 402 and the first voltage level VSSA. A parasitic BJT 408, having an emitter, a base, and a collector, is formed among the first voltage level VSSA, the second voltage level VDDA, and the signal input/output point 402, and the emitter of the parasitic BJT 408 is couple to the second voltage level VDDA, the base of the parasitic BJT 408 is couple to the first voltage level VSSA, and the collector of the parasitic BJT 408 is couple to the signal input/output point 402.

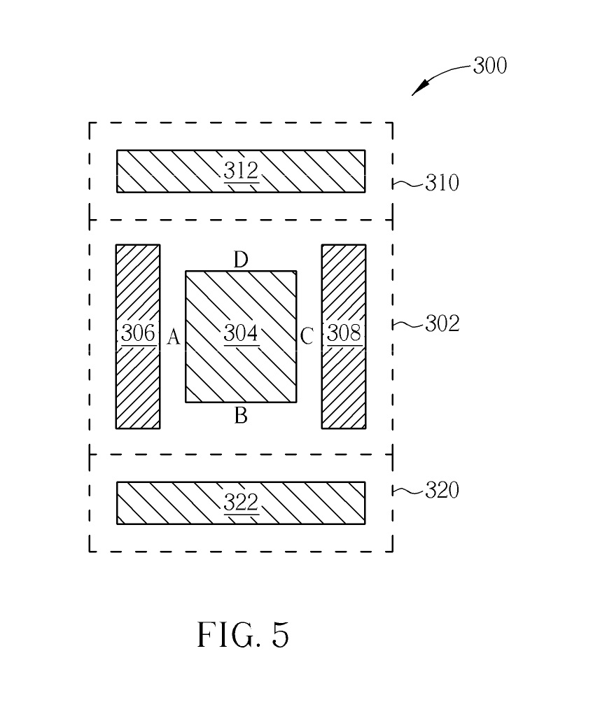

In a second embodiment shown in FIG. 5, the semiconductor structure 300 in FIG. 3 can further comprises: a second N-well 320 positioned in the second side B of the first N+ diffusion region 304 and adjacent to the P-well 302, and a third N+ diffusion region 322 positioned in the second N-well 320 and coupled to the second voltage level VDDA, wherein the second N-well 320 has no P+ diffusion region disposed therein.

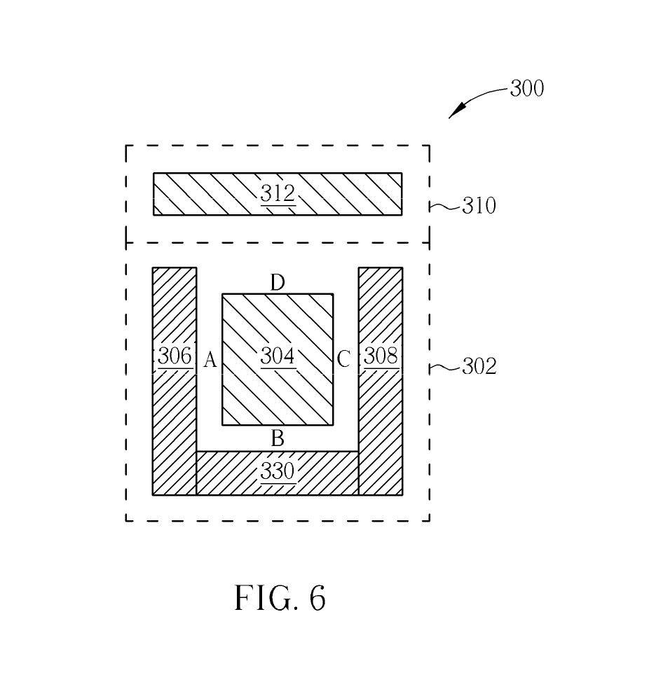

In a third embodiment shown in FIG. 6, the semiconductor structure 300 in FIG. 3 can further comprises: a third P+ diffusion region 330 positioned in the P-well 302 and in the second side B of the first N+ diffusion region 304, and coupled to the first voltage level VSSA.

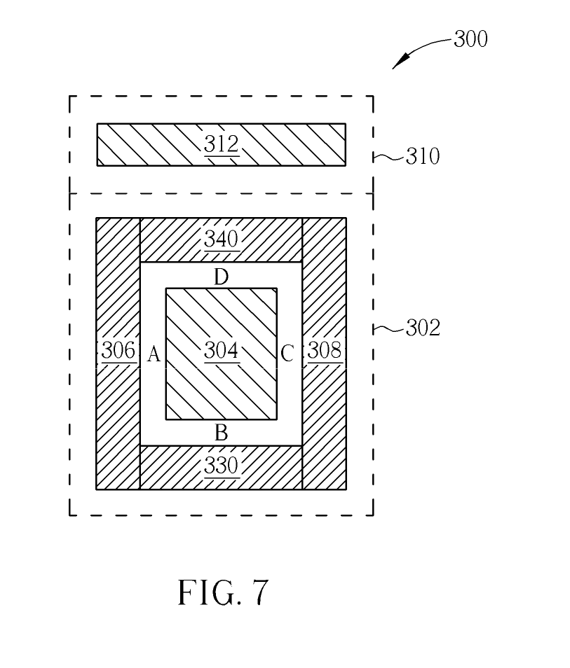

In a fourth embodiment shown in FIG. 7, the semiconductor structure 300 in FIG. 6 can further comprises: a fourth P+ diffusion region 340, positioned in the P-well 302 and in the fourth side D of the first N+ diffusion region 304, and coupled to the first voltage level VSSA.

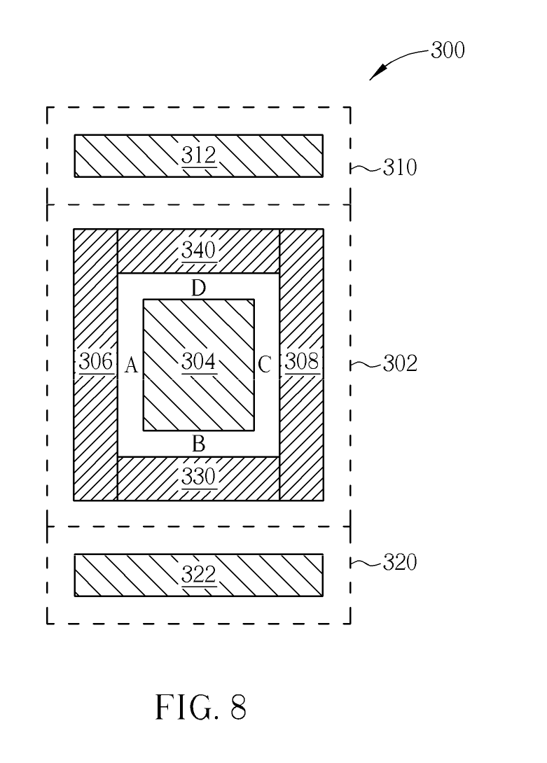

In a fifth embodiment shown in FIG. 8, the semiconductor structure 300 in FIG. 7 can further comprises: a second N-well 320 positioned in the second side B of the first N+ diffusion region 304 and adjacent to the P-well 302, and a third N+ diffusion region 322 positioned in the second N-well 320 and coupled to the second voltage level VDDA, wherein the second N-well 320 has no P+ diffusion region disposed therein.

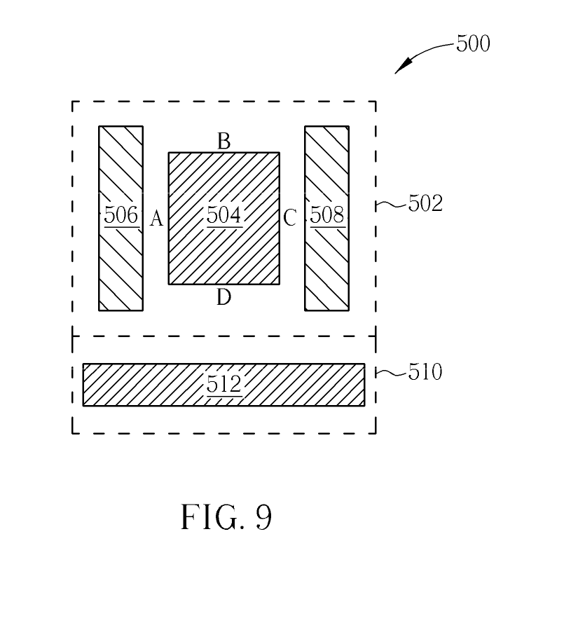

The embodiments shown in FIG. 3 to FIG. 8 are N-type semiconductor structures. Next, embodiments of P-type semiconductor structures will be shown in FIG. 9 to FIG. 14 in the following paragraphs.

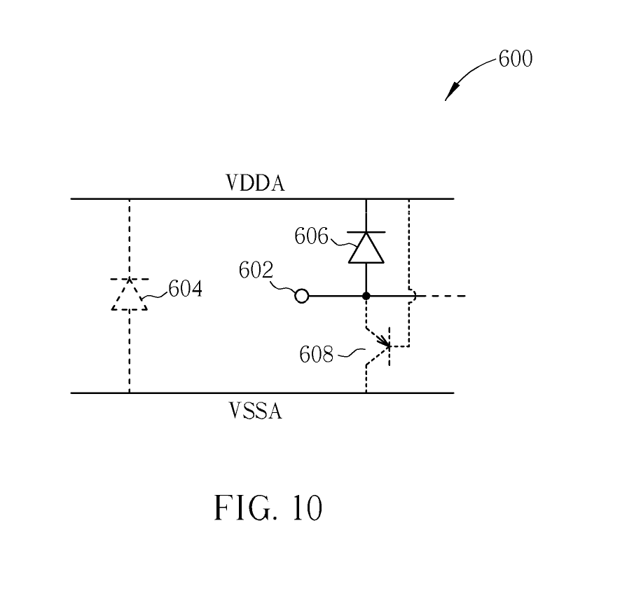

Please refer to FIG. 9 and FIG. 10. FIG. 9 shows a simplified diagram of a semiconductor structure 500 in accordance with a sixth embodiment of the present invention. FIG. 10 shows an ESD protection circuit 600 realized by the semiconductor structure 500. As shown in FIG. 9, the semiconductor structure 500 comprises: a N-well 502, a first P+ diffusion region 504, a first N+ diffusion region 506, a second N+ diffusion region 508, a first P-well 510, and a second P+ diffusion region 512. The first P+ diffusion region 504 is positioned in the N-well 502, and has a first side A, a second side B adjacent to the first side A, a third side C adjacent to the second side B, and a fourth side D adjacent to the first side A and the third side C, and the first P+ diffusion region 504 is coupled to a signal input/output point 602 (shown in FIG. 10). The first N+ diffusion region 506 is positioned in the N-well 502 and in the first side A of the first P+ diffusion region 504, and coupled to a first voltage level VDDA. The second N+ diffusion region 508 is positioned in the N-well 502 and in the third side C of the first P+ diffusion region 504, and coupled to the first voltage level VDDA. The first P-well 510 is positioned in the fourth side D of the first P+ diffusion region 504 and adjacent to the N-well 502. The second P+ diffusion region 512 is positioned in the first P-well 510 and coupled to a second voltage level VSSA, wherein the second voltage level VSSA is lower than the first voltage level VDDA. The first P-well 510 has no N+ diffusion region disposed therein. The semiconductor structure 500 realizes the ESD protection circuit 600 as shown in FIG. 10. A first diode 604 is formed between the first voltage level VDDA and the second voltage level VSSA, and a second diode 606 is formed between the signal input/output point 602 and the first voltage level VDDA. A parasitic BJT 608 having an emitter, a base, and a collector, is formed among the first voltage level VDDA, the second voltage level VSSA, and the signal input/output point 602, and the emitter of the parasitic BJT 608 is couple to the signal input/output point 602, and the base of the parasitic BJT 608 is couple to the first voltage level VDDA, and the collector of the parasitic BJT 608 is couple to the second voltage level VSSA.

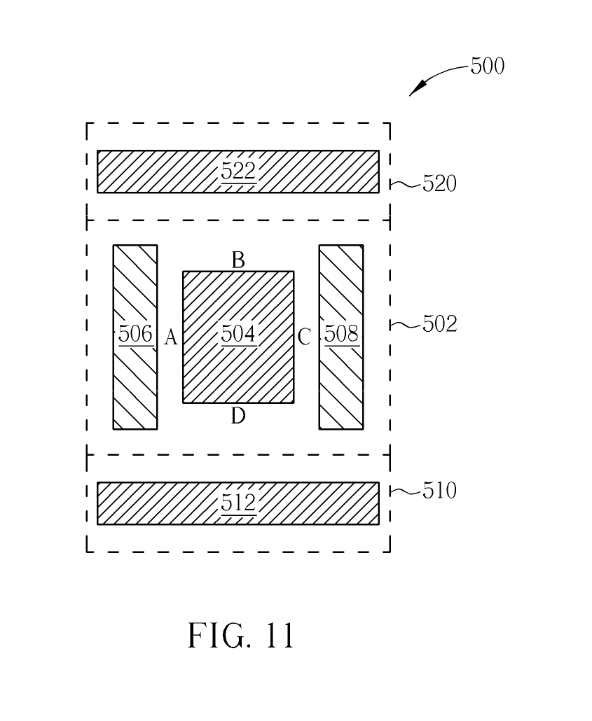

In a seventh embodiment shown in FIG. 11, the semiconductor structure 500 in FIG. 9 can further comprises: a second P-well 520 positioned in the second side B of the first P+ diffusion region 504 and adjacent to the N-well 502, and a third P+ diffusion region 522 positioned in the second P-well 520 and coupled to the second voltage level VSSA, wherein the second P-well 520 has no N+ diffusion region disposed therein.

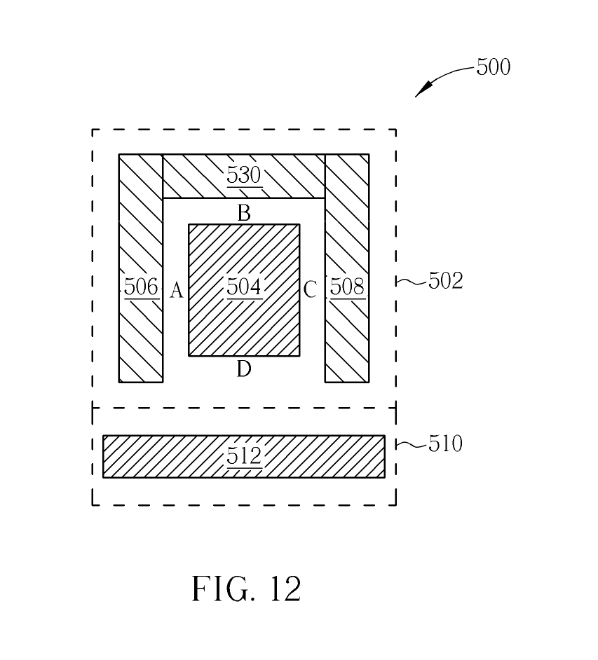

In an eighth embodiment shown in FIG. 12, the semiconductor structure 500 in FIG. 9 can further comprises: a third N+ diffusion region 530 positioned in the N-well 502 and in the second side B of the first P+ diffusion region 504 and coupled to the first voltage level VDDA.

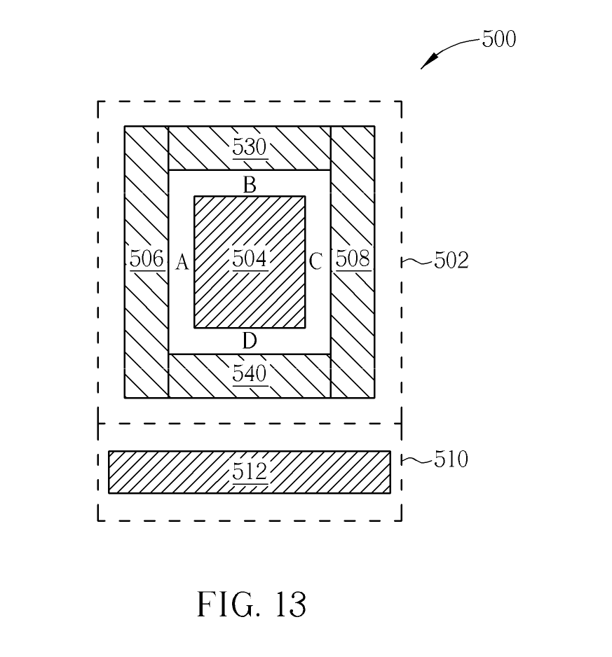

In a ninth embodiment shown in FIG. 13, the semiconductor structure 500 in FIG. 12 can further comprises: a fourth N+ diffusion region 540 positioned in the N-well 502 and in the fourth side D of the first P+ diffusion region 504 and coupled to the first voltage level VDDA.

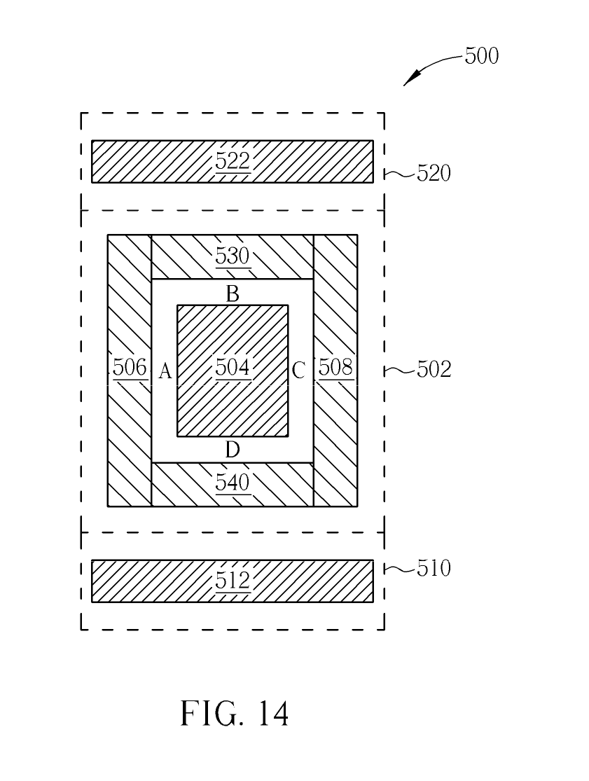

In a tenth embodiment shown in FIG. 14, the semiconductor structure 500 in FIG. 13 can further comprises: a second P-well 520 positioned in the second side B of the first P+ diffusion region 504 and adjacent to the N-well 502, and a third P+ diffusion region 522 positioned in the second P-well and coupled to the second voltage level VSSA, wherein the second P-well 520 has no N+ diffusion region disposed therein.

Please note that the above embodiments are only for illustrative purposes and are not meant to be limitations of the present invention. Compared with the conventional semiconductor structure for realizing an ESD protection circuit, the semiconductor structure disclosed by the present invention requires a smaller area by utilizing the parasitic BJT to have the same ESD protection function. Brief summarized, the semiconductor structure disclosed by the present invention can be utilized for realizing an ESD protection circuit in a smaller area to reduce cost.

Those skilled in the art will readily observe that numerous modifications and alterations of the device and method may be made while retaining the teachings of the invention.

What is claimed is:

1. A semiconductor structure for realizing an ESD protection circuit, comprising:
a P-well;
a first N+ diffusion region, positioned in the P-well, having a first side, a second side adjacent to the first side, a third side adjacent to the second side, and a fourth side adjacent to the first side and the third side, and coupled to a signal input/output point;
a first P+ diffusion region, positioned in the P-well and in the first side of the first N+ diffusion region, and coupled to a first voltage level;
a second P+ diffusion region, positioned in the P-well and in the third side of the first N+ diffusion region, and coupled to the first voltage level;
a first N-well, positioned in the fourth side of the first N+ diffusion region and adjacent to the P-well; and
a second N+ diffusion region, positioned in the first N-well and coupled to a second voltage level, wherein the second voltage level is higher than the first voltage level;
wherein the first N-well has no P+ diffusion region disposed therein, a first diode is formed between the first voltage level and the second voltage level, a second diode is formed between the signal input/output point and the first voltage level, and a parasitic BJT, having an emitter, a base, and a collector, is formed among the first voltage level, the second voltage level, and the signal input/output point, and the emitter of the parasitic BJT is couple to the second voltage level, the base of the parasitic BJT is couple to the first voltage level, and the collector of the parasitic BJT is couple to the signal input/output point.

2. The semiconductor structure of claim 1, further comprising:
a second N-well, positioned in the second side of the first N+ diffusion region and adjacent to the P-well; and
a third N+ diffusion region, positioned in the second N-well and coupled to the second voltage level.

3. The semiconductor structure of claim 2, wherein the second N-well has no P+ diffusion region disposed therein.

4. The semiconductor structure of claim 1, further comprising:
a third P+ diffusion region, positioned in the P-well and in the second side of the first N+ diffusion region, and coupled to the first voltage level.

5. The semiconductor structure of claim 4, further comprising:
a fourth P+ diffusion region, positioned in the P-well and in the fourth side of the first N+ diffusion region, and coupled to the first voltage level.

6. The semiconductor structure of claim 5, further comprising:
a second N-well, positioned in the second side of the first N+ diffusion region and adjacent to the P-well; and
a third N+ diffusion region, positioned in the second N-well and coupled to the second voltage level.

7. The semiconductor structure of claim 6, wherein the second N-well has no P+ diffusion region disposed therein.

8. A semiconductor structure for realizing an ESD protection circuit, comprising:
a N-well;
a first P+ diffusion region, positioned in the N-well, having a first side, a second side adjacent to the first side, a third side adjacent to the second side, and a fourth side adjacent to the first side and the third side, and coupled to a signal input/output point;
a first N+ diffusion region, positioned in the N-well and in the first side of the first P+ diffusion region, and coupled to a first voltage level;
a second N+ diffusion region, positioned in the N-well and in the third side of the first P+ diffusion region, and coupled to the first voltage level;
a first P-well, positioned in the fourth side of the first P+ diffusion region and adjacent to the N-well; and
a second P+ diffusion region, positioned in the first P-well and coupled to a second voltage level, wherein the second voltage level is lower than the first voltage level;
wherein the first P-well has no N+ diffusion region disposed therein, a first diode is formed between the first voltage level and the second voltage level, a second diode is formed between the signal input/output point and the first voltage level, and a parasitic BJT having an emitter, a base, and a collector is formed among the first voltage level, the second voltage level, and the signal input/output point, and the emitter of the parasitic BJT is couple to the signal input/output point, the base of the parasitic BJT is couple to the first voltage level, and the collector of the parasitic BJT is couple to the second voltage level.

9. The semiconductor structure of claim 8, further comprising:
a second P-well, positioned in the second side of the first P+ diffusion region and adjacent to the N-well; and
a third P+ diffusion region, positioned in the second P-well and coupled to the second voltage level.

10. The semiconductor structure of claim 9, wherein the second P-well has no N+ diffusion region disposed therein.

11. The semiconductor structure of claim 8, further comprising:
a third N+ diffusion region, positioned in the N-well and in the second side of the first P+ diffusion region, and coupled to the first voltage level.

12. The semiconductor structure of claim 11, further comprising:
a fourth N+ diffusion region, positioned in the N-well and in the fourth side of the first P+ diffusion region, and coupled to the first voltage level.

13. The semiconductor structure of claim 12, further comprising:
a second P-well, positioned in the second side of the first P+ diffusion region and adjacent to the N-well; and
a third P+ diffusion region, positioned in the second P-well and coupled to the second voltage level.

14. The semiconductor structure of claim 13, wherein the second P-well has no N+ diffusion region disposed therein.
